(19) United States
(12) Patent Application Publication
(10) Pub. No.: US 2020/0168846 A1
(43) Pub. Date: May 28, 2020

(54) A MASK USED FOR THIN-FILM ENCAPSULATION OF A FLEXIBLE OLED PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xiao DU, Wuhan, Hubei (CN)

(21) Appl. No.: 16/320,382

(22) PCT Filed: Jan. 2, 2019
(86) PCT No.: PCT/CN2019/070130

§ 371 Date: Jan. 24, 2019

(30) Foreign Application Priority Data
Nov. 26, 2018 (CN) 201811415668.7

(51) Int. Cl. H01L 51/56; H01L 27/32; H01L 51/00; H01L 51/52; C23C 16/04

(52) U.S. Cl. CPC H01L 51/56; H01L 27/3211; H01L 2251/5338; H01L 51/5253; C23C 16/042; H01L 51/0097

(57) ABSTRACT

The present invention provides a mask used for thin-film encapsulation of a flexible OLED panel, including a mask frame and a mask housing disposed in the mask frame. The mask housing defines a shadow region and an opening region. The opening region is corresponding to an active area of the flexible OLED panel. The opening region defines a precision mask region, which is corresponding to a bending area of the flexible OLED panel. The precision mask region defines multiple precision openings separated from each other, and each precision opening is corresponding to one or more pixels. The mask provided in the present invention can make multiple modular encapsulation structures, thereby reducing an internal stress of an inorganic encapsulation layer when bending, and further reducing the risk of damage to the inorganic encapsulation layer during repeated bending.

### BACKGROUND OF THE INVENTION

### 1. Field of the Invention

The present invention relates to an encapsulation technology field of display devices, and more particularly to a mask used for thin-film encapsulation of a flexible OLED panel.

### 2. Description of the Prior Art

With the development of mobile communication technology, mobile phone functions have been greatly developed. The development of smart phones tends to be big screen, but oversize screens can affect the portable performance of mobile phones. Therefore, foldable smart phones have attracted great attention in the field of the mobile communications.

Now, with the continuous development of OLED display technology, a flexible OLED panel has achieved mass production, and its main focus is on a curved screen. But there are still many problems to be solved urgently in the development process of foldable flexible OLED substrates. The main problem is that a bending zone of the flexible substrate is not durable enough when folded repeatedly. This is due to the different stress of each film in the bending zone, which may cause the separation of the film or the destruction of the encapsulation layer in the process of repeated bending.

Furthermore, the glass encapsulation technology used in a traditional display panel is difficult to meet the flexible requirement. At this stage, the main packaging method used in flexible panel is TFE (Thin Film Encapsulation) technology. At present, the TFE used in mass production is Barix encapsulation technology. The principle is to construct multilayer films with alternating inorganic-organic layer on the substrate surface by a chemical vapor deposition method and an ink jet printing method, so as to complete the encapsulation of the substrate. The function layer for blocking water and oxygen is the inorganic encapsulation layer. The main function of the organic layer is to disperse the internal stress of the inorganic layer when bending the substrate. Moreover, because the inorganic layer is a rigid layer, when bending, the inorganic layer is easily separated from the substrate due to the excessive internal stress of the inorganic layer, or the inorganic layer breaks or falls off due to uneven stress. All of these will result in the failure of the encapsulation.

Hence, it is necessary to design a mask used for thin-film encapsulation of a flexible OLED panel to overcome the shortcomings of the existing technology.

### BRIEF SUMMARY OF THE INVENTION

An aspect of the invention is to provide a mask used for thin-film encapsulation of a flexible OLED panel, which can transform an inorganic encapsulation layer on a bending area of the OLED panel from an original integral encapsulation layer to multiple independent modular encapsulation structures, thereby reducing an internal stress of the inorganic encapsulation layer when bending, and further reducing the risk of damage to the inorganic encapsulation layer during repeated bending.

The technical scheme adopted by the present invention is as follows.

A mask used for thin-film encapsulation of a flexible OLED panel comprises a mask frame and a mask housing disposed in the mask frame. Wherein the mask housing defines a shadow region and an opening region. The opening region is corresponding to an active area of the flexible OLED panel. The opening region defines a precision mask region, which is corresponding to a bending area of the flexible OLED panel. The precision mask region defines multiple precision openings separated from each other, and each precision opening is corresponding to one or more pixels in the bending area.

Further, in the different embodiments, each precision opening is corresponding to one pixel including red, green and blue sub-pixels, in the bending area of the OLED panel.

Or each precision opening is corresponding to three pixels representing red, green and blue pixels respectively, in the bending area of the OLED panel. In other embodiments, each precision opening is preferably corresponding to three pixels or an integer multiple of three pixels (e.g. 6, 9, 12 etc), which are corresponding to red, green and blue pixels in actual use.

Further, in the different embodiment, each precision opening is corresponding to a row of pixels perpendicular to a bending direction of the bending area of the OLED panel.

Further, in the different embodiment, each precision opening is corresponding to 2-N pixels arranged to be different pattern in the bending area of the OLED panel, where N is an integer equal to or greater than three.

Wherein in the different embodiments, the number of the precision openings defined by the precision mask region can be 3, 4, 5, 6, 7, 8, 9, 10, and so on, depending on the actual needs, but there is no limit. Correspondingly, the precision openings can be of the same size or of different sizes. The precision openings can be corresponding to the same number of pixels or different number of pixels respectively. It can be decided according to actual needs, and there is no limit.

Further, in the different embodiment, the precision mask region is corresponding to the bending area and extends 100-1000 μm toward both sides thereof.

Further, in the different embodiment, the precision mask region is formed by a method of electroforming, etching or metal wire drawing.

Further, in the different embodiment, the opening region is corresponding to the active area and extends 100-500 um outward.

Further, in the different embodiment, the mask housing defines two or more opening regions, at least one of which defines the precision mask region.

Further, in the different embodiment, a thickness of the mask housing is 0.02-0.2 mm.

Further, in the different embodiment, a surface of the mask housing is covered with protective films, which may be PTFE coatings or Al₂O₃ inorganic coatings.

Comparing with the prior art, the present invention has the advantages that a design concept of a precise metal mask is introduced into the mask used for thin-film encapsulation of the flexible OLED panel, and the metal mask originally used in packaging process is partially or wholly designed as a precise metal mask region with PPI slightly lower than that of the substrate PPI. After design modification, the mask of the present invention can partially or wholly divide the encapsulation region of the inorganic encapsulation layer. Thus, the inorganic encapsulation layer of the bending area of the flexible OLED panel, which is made by the mask of the present invention, can be transformed from the original integral encapsulation layer to multiple independent modular encapsulation structures, thereby reducing an internal stress of the inorganic encapsulation layer when bending, and further reducing the risk of damage to the inorganic encapsulation layer during repeated bending.

### BRIEF DESCRIPTION OF THE DRAWINGS

For more clearly understanding above content of the present invention, the following text will briefly introduce the accompanying drawings used in the preferred embodiment of the present invention. It is obvious that the accompanying drawings in the following description are only some embodiments of the present invention. For the technical personnel of the field, other drawings can also be obtained from these drawings without paying creative work.

FIG. 1 is a structure schematic view of a mask used for thin-film encapsulation of a flexible OLED panel in one embodiment of the present invention;

FIG. 2 is a structure schematic view, which shows a first embodiment of a precision opening defined by a precision mask region of the mask of FIG. 1;

FIG. 3 is a structure schematic view, which shows a second embodiment of a precision opening defined by a precision mask region of the mask of FIG. 1:

FIG. 4 is a structure schematic view, which shows a third embodiment of a precision opening defined by a precision mask region of the mask of FIG. 1;

FIG. 5 is a top view of a flexible OLED substrate encapsulated using the mask described in the present invention;

FIG. 6 is a cross-sectional view of the flexible OLED substrate shown in FIG. 5; and

FIG. 7 is a structure schematic view of the mask used for thin-film encapsulation of the flexible OLED panel in another embodiment of the present invention.

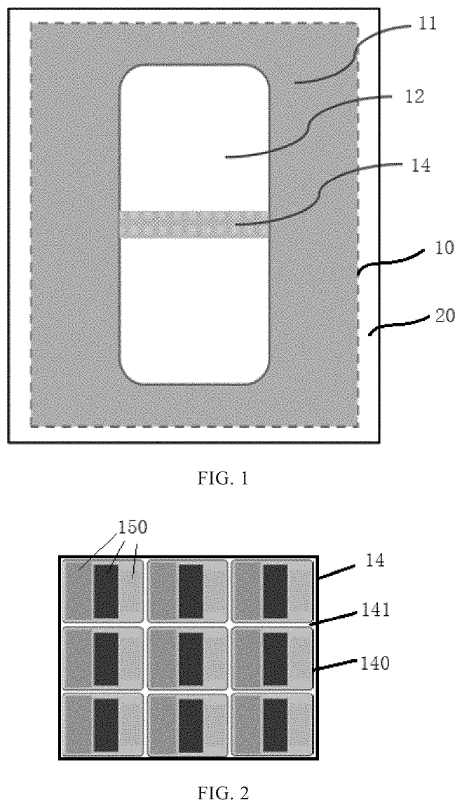

Reference numerals in FIGS. 1-7:

| | | | |
|---|---|---|---|
| mask housing | 10 | shadow region | 11 |
| opening region | 12 | precision mask region | 14 |
| precision opening | 140 | gap | 141 |
| pixel | 150 | integral encapsulation | 110 |
| | | region | |
| modular encapsulation | 120 | OLED substrate | 130 |
| region | | | |
| modular encapsulation | 132 | mask frame | 20 |
| structure | | | |

### DETAILED DESCRIPTION OF THE PREFERRED EMBODIMENTS

The following text will give a further detailed description of the technical scheme of a mask used for thin-film encapsulation of a flexible OLED panel with reference to the accompanying drawings and embodiments.

Please refer to FIG. 1, in one embodiment, the present invention provides a mask used for thin-film encapsulation of a flexible OLED panel. The mask includes a mask frame 20 and a mask housing 10 disposed in the mask frame 20.

The mask housing 10 defines a shadow region 11 and an opening region 12. The opening region 12 is corresponding to an active area (AA) of the flexible OLED panel. The opening region 12 defines a precision mask region 14 being corresponding to a bending area of the flexible OLED panel.

The mask housing 10 is fixed on the mask frame 20 by laser spot welding. A thickness of the mask housing 10 is 0.02-0.2 mm. A surface of the mask housing 10 can be covered with protective films such as Al₂O₃ or PTFE coatings to prevent the mask from being damaged in a TFE process. The opening region 12 is corresponding to the active area, and extends 100-500 um outward, but is not limited to this. It can be decided according to actual needs. The precision mask region 14 can be formed by a method of electroforming, etching or metal wire drawing. The precision mask region 14 is corresponding to the bending area, and extends 100-1000 μm toward both sides thereof.

Further, the precision mask region defines multiple precision openings separated from each other. Each precision opening is corresponding to one or more pixels in the bending area of the flexible OLED panel. Specifically, please refer to FIGS. 2-4, three embodiments of the precision openings are shown therein, but these embodiments are illustrative only, without any limitation, and a person skilled in the art may make equivalent or combination transformations according to these embodiments.

Specifically, please refer to FIG. 2, it shows that the precision mask region 14 has nine precision openings 140 of the same size and there is a gap 141 between each two adjacent precise openings. Each precision opening is corresponding to three pixels 150.

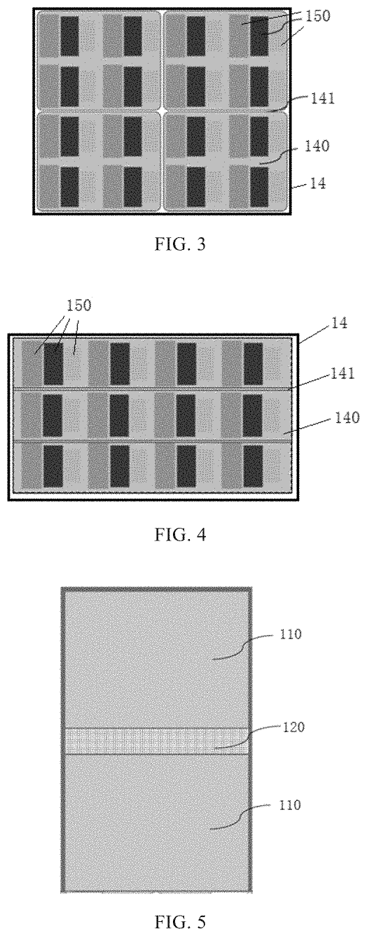

Please refer to FIG. 3, it shows that the precision mask region 14 has four precision openings 140 of the same size and there is a gap 141 between each two adjacent precise openings. Each precision opening is corresponding to six pixels 150.

Please refer to FIG. 4, it shows that the precision mask region 14 has three precision openings 140 of the same size and there is a gap 141 between each two adjacent precise openings. Each precision opening is corresponding to a row of pixels 150. The row of pixels 150 may be corresponding to a transverse row of pixels of the bending area.

Furthermore, in different embodiments, the number of the precision openings 140 defined by the precision mask region 14 can be 3, 4, 5, 6, 7, 8, 9, 10, and so on, depending on the actual needs. But there is no limit. Correspondingly, the precision openings can be of the same size or of different sizes. The precision openings can be corresponding to the same number of pixels or different number of pixels respectively. It can be decided according to actual needs, and there is no limit.

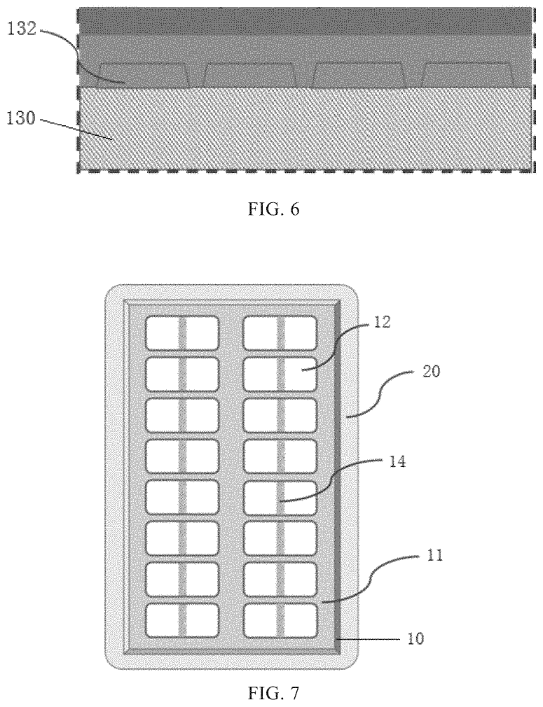

The mask described in the present invention can be used to encapsulate a flexible OLED substrate. Please refer to FIGS. 5 and 6, the encapsulated flexible OLED substrate are shown therein. An encapsulation area on the OLED substrate includes an integral encapsulation region 110 and a modular encapsulation region 120. There is an inorganic encapsulation layer on the OLED substrate 130 of the modular encapsulation region 120. After applying the mask of the present invention and being masked by the precision mask region 14, an encapsulation structure of the inorganic encapsulation layer is transformed from an original integral encapsulation layer to multiple independent modular encapsulation structures 132, thereby reducing an internal stress of the whole inorganic encapsulation layer of the bending area when bending, and further reducing the risk of damage to the inorganic encapsulation layer in the bending area of the flexible OLED substrate during repeated bending.

Furthermore, please refer to FIG. 7, which shows another embodiment of the mask used for thin-film encapsulation of the flexible OLED panel of the present invention. The mask includes a mask frame 20 and a mask housing 10 disposed in the mask frame 20.

The mask housing 10 defines a shadow region 11 and multiple opening regions 12. Each opening regions 12 is corresponding to an active area (AA) of the flexible OLED panel, and each opening region 12 defines a precision mask region 14 being corresponding to a bending area of the flexible OLED panel.

The difference between the embodiment shown in FIG. 7 and the embodiment shown in FIG. 1 is that, the embodiment of FIG. 7 includes the single opening region 12, but the embodiment of FIG. 7 includes multiple opening regions 12. But there is no substantial difference in the specific structure of each opening region. Therefore, in order to avoid unnecessary redundancy, we will not repeat here.

The technical scope of the present invention is not limited to the contents of the above description. A person in the art can make various modifications for the above embodiments without departing from the technical ideas of the present invention, and the modifications shall be included in the scope of protection of the invention.

What is claimed is:

1. A mask used for thin-film encapsulation of a flexible OLED panel, comprising a mask frame and a mask housing disposed in the mask frame;
wherein the mask housing defines a shadow region and an opening region, the opening region being corresponding to an active area of the flexible OLED panel;
the opening region defining a precision mask region, which is corresponding to a bending area of the flexible OLED panel; and
the precision mask region defining multiple precision openings separated from each other, and each precision opening being corresponding to one or more pixels in the bending area.

2. The mask used for thin-film encapsulation of the flexible OLED panel as claimed in claim 1, wherein each precision opening is corresponding to one pixel including red, green and blue sub-pixels, in the bending area of the OLED panel.

3. The mask used for thin-film encapsulation of the flexible OLED panel as claimed in claim 1, wherein each precision opening is corresponding to a row of pixels perpendicular to a bending direction of the bending area of the OLED panel.

4. The mask used for thin-film encapsulation of the flexible OLED panel as claimed in claim 1, wherein each precision opening is corresponding to 2-N pixels arranged to be different pattern in the bending area of the OLED panel, where N is an integer equal to or greater than three.

5. The mask used for thin-film encapsulation of the flexible OLED panel as claimed in claim 1, wherein the precision mask region is corresponding to the bending area and extends 100-1000 μm toward both sides thereof.

6. The mask used for thin-film encapsulation of the flexible OLED panel as claimed in claim 1, wherein the precision mask region is formed by a method of electroforming, etching or metal wire drawing.

7. The mask used for thin-film encapsulation of the flexible OLED panel as claimed in claim 1, wherein the opening region is corresponding to the active area and extends 100-500 um outward.

8. The mask used for thin-film encapsulation of the flexible OLED panel as claimed in claim 1, wherein the mask housing defines two or more opening regions, at least one of which defines the precision mask region.

9. The mask used for thin-film encapsulation of the flexible OLED panel as claimed in claim 1, wherein a thickness of the mask housing is 0.02-0.2 mm.

10. The mask used for thin-film encapsulation of the flexible OLED panel as claimed in claim 1, wherein a surface of the mask housing is covered with protective films, which may be PTFE coatings or Al₂O₃ inorganic coatings.
